(19) United States
(12) Patent Application Publication
(10) Pub. No.: US 2026/0136708 A1
(43) Pub. Date: May 14, 2026

(54) SUBSTRATES HAVING A BROADBAND ANTIREFLECTION LAYER AND METHODS OF FORMING A BROADBAND ANTIREFLECTION LAYER

(71) Applicant: University of Florida Research Foundation, Inc., Gainesville, FL (US)

(72) Inventors: Peng Jiang, Gainesville, FL (US); Zhuxiao Gu, Gainesville, FL (US); Ruwen Tan, Gainesville, FL (US)

(21) Appl. No.: 19/012,117

(22) Filed: Jan. 7, 2025

Related U.S. Application Data
(63) Continuation of application No. 18/203,436, filed on May 30, 2023, now Pat. No. 12,224,362.
Application No. 18/203,436 is a continuation of application No. 16/956,029, now Pat. No. 11,705,527.
(60) Provisional application No. 62/608,858, filed on Dec. 21, 2017.

(51) Int. Cl. H10F 77/30; G02B 1/118; H10F 71/00

(52) U.S. Cl. CPC H10F 77/315; G02B 1/118; H10F 71/00

(57) ABSTRACT

Embodiments of the present disclosure provide for methods of making substrates having an (AR) antireflective layer, substrates having an antireflective layer, devices including a substrate having an antireflective layer, and the like. The AR layer can have a total specular reflection of less than 10% at a wavelength of about 400-800 nm, and a height of about 500-1000 nm.

### CROSS-REFERENCE TO RELATED APPLICATIONS

This application is a continuation of U.S. application Ser. No. 18/203,436, filed on May 30, 2023, which is a continuation of U.S. application Ser. No. 16/956,029, filed on Jun. 19, 2020, which is the 35 U.S.C. § 371 national stage of PCT application having serial number PCT/US2018/066234, filed on Dec. 18, 2018. This application also claims the benefit of and priority to U.S. Provisional Application Ser. No. 62/608,858, having the title “SUBSTRATES HAVING A BROADBAND ANTIREFLECTION LAYER AND METHODS OF FORMING A BROADBAND ANTIREFLECTION LAYER”, filed on Dec. 21, 2018, the disclosures of each which are incorporated herein by reference in their entireties.

### FEDERAL SPONSORSHIP

This invention was made with government support under HDTRA1-15-1-022 awarded by the Department of Defense/Defense Threat Reduction Agency; and under CMMI1562861 awarded by the National Science Foundation. The government has certain rights in the invention.

### BACKGROUND

Antireflective layers or substrates can be useful in many technologies such as solar cell and diodes. However, currently technologies for making antireflective layers can be cumbersome and costly. Also, the antireflective layers may not be suitable for the environments that some technologies have to operate in. Thus there is a need to overcome these and other deficiencies and hurdles.

### SUMMARY

Embodiments of the present disclosure provide structures and substrates including broadband antireflective layers, methods of making broadband antireflective layers and the like.

An embodiment of the present disclosure includes methods of forming broadband antireflective layers on a substrate, including: providing the substrate, wherein a polyimide substrate is disposed over a first area of the substrate, and wherein a second area of the substrate does not include the polyimide substrate; etching the substrate having the polyimide substrate; and forming the broadband antireflective layer on the second area of the substrate.

An embodiment of the present disclosure also includes structures made using the methods described herein.

An embodiment of the present disclosure also includes structures including a substrate having a broadband antireflective layer that can have a total specular reflection of less than 10% at a wavelength of about 400 to about 800 nm. The broadband antireflective layer can have a plurality of pillars that are not uniformly spaced apart from one another. The broadband antireflective layer can have a height of about 500 nm to about 1000 nm, and the plurality of pillars can be spaced about 10 nm to 300 nm between a pair of pillars as measured from pillar base to pillar base. A pillar can have a diameter at the base of about 50 to 300 nm.

An embodiment of the present disclosure also includes structures including a base substrate including a polyimide substrate disposed over a first area of the base substrate and second area having a broadband antireflective layer that can have a total specular reflection of less than 10% at a wavelength of about 400 to about 800 nm. The broadband antireflective layer can have a plurality of pillars that are not uniformly spaced apart from one another. The broadband antireflective layer can have a height of about 500 nm to about 1000 nm, and the plurality of pillars can be spaced about 10 nm to 300 nm between a pair of pillars as measured from pillar base to pillar base. A pillar can have a diameter at the base of about 50 to 300 nm.

Other compositions, apparatus, methods, features, and advantages will be or become apparent to one with skill in the art upon examination of the following drawings and detailed description. It is intended that all such additional compositions, apparatus, methods, features and advantages be included within this description, be within the scope of the present disclosure, and be protected by the accompanying claims.

### BRIEF DESCRIPTION OF THE DRAWINGS

Further aspects of the present disclosure will be more readily appreciated upon review of the detailed description of its various embodiments, described below, when taken in conjunction with the accompanying drawings.

FIGS. 1A-1D are example photographs of (1A) Black silicon (BSi) wafer with the tape on the surface, (1B) the same wafer with the tape peeled off, (1C) BSi wafer with a “UF” pattern with the tape peeled off, (1D) comparison between the BSi (left) and moth-eye (right) coatings prepared using the same RIE process.

FIG. 2A provides AFM 3-D reconstruction of a 25 μm2 area of the BSi surface, (2B) height profile along the X axis, (2C) height profile along the Y axis.

FIGS. 3A and 3B are example SEM images of (3A) the BSi surface (left) and tape-covered area (right) with a clear boundary, (3B) magnified region of the BSi surface.

FIG. 4 provides normal-incidence optical reflection spectra obtained from different regions of the BSi half wafer and the moth-eye half wafer shown in FIG. 1D.

FIG. 5 shows XPS analysis of the elemental composition of the BSi surface.

The drawings illustrate only example embodiments and are therefore not to be considered limiting of the scope described herein, as other equally effective embodiments are within the scope and spirit of this disclosure. The elements and features shown in the drawings are not necessarily drawn to scale, emphasis instead being placed upon clearly illustrating the principles of the embodiments. Additionally, certain dimensions may be exaggerated to help visually convey certain principles. In the drawings, similar reference numerals between figures designate like or corresponding, but not necessarily the same, elements.

### DETAILED DESCRIPTION

This disclosure is not limited to particular embodiments described, and as such may, of course, vary. The terminology used herein serves the purpose of describing particular embodiments only, and is not intended to be limiting, since the scope of the present disclosure will be limited only by the appended claims.

Where a range of values is provided, each intervening value, to the tenth of the unit of the lower limit unless the context clearly dictates otherwise, between the upper and lower limit of that range and any other stated or intervening value in that stated range, is encompassed within the disclosure. The upper and lower limits of these smaller ranges may independently be included in the smaller ranges and are also encompassed within the disclosure, subject to any specifically excluded limit in the stated range. Where the stated range includes one or both of the limits, ranges excluding either or both of those included limits are also included in the disclosure.

Embodiments of the present disclosure will employ, unless otherwise indicated, techniques of chemistry, material science, and the like, which are within the skill of the art. Such techniques are explained fully in the literature.

The following examples are put forth so as to provide those of ordinary skill in the art with a complete disclosure and description of how to perform the methods and use the structures disclosed and claimed herein. Efforts have been made to ensure accuracy with respect to numbers (e.g., amounts, temperature, etc.), but some errors and deviations should be accounted for. Unless indicated otherwise, parts are parts by weight, temperature is in ° C., and pressure is at or near atmospheric. Standard temperature and pressure are defined as 20° C. and 1 atmosphere.

Before the embodiments of the present disclosure are described in detail, it is to be understood that, unless otherwise indicated, the present disclosure is not limited to particular materials, reagents, reaction materials, manufacturing processes, dimensions, frequency ranges, applications, or the like, as such can vary. It is also to be understood that the terminology used herein is for purposes of describing particular embodiments only, and is not intended to be limiting. It is also possible in the present disclosure that steps can be executed in different sequence, where this is logically possible. It is also possible that the embodiments of the present disclosure can be applied to additional embodiments involving measurements beyond the examples described herein, which are not intended to be limiting. It is furthermore possible that the embodiments of the present disclosure can be combined or integrated with other measurement techniques beyond the examples described herein, which are not intended to be limiting.

It should be noted that, as used in the specification and the appended claims, the singular forms “a,” “an,” and “the” include plural referents unless the context clearly dictates otherwise. Thus, for example, reference to “a support” includes a plurality of supports. In this specification and in the claims that follow, reference will be made to a number of terms that shall be defined to have the following meanings unless a contrary intention is apparent.

### Discussion

Embodiments of the present disclosure provide for methods of making substrates having an antireflective layer, substrates having an antireflective layer, devices including a substrate having an antireflective layer, and the like. Embodiments of the substrate are advantageous over other substrates due to the high thermal, radiation stability, and/or lifetime of the antireflective layer of the substrates. Embodiments of the substrate can be used in solar cells, thermophotovoltaic cells, organic light emitting diodes (OLEDs), and semiconductor light emitting diodes.

In an aspect, the method of forming the substrate having an antireflective layer is simple relative to other techniques and does not require a lithographic process, which can be advantageous in speed of processing and overall reduced cost. In an embodiment, the antireflective layer is formed from the substrate and involves only a single step, which enhances the mechanical and environmental stability of the substrate and antireflective coating. In an embodiment, the antireflective layer can have a total specular reflection that is much less than other substrates (e.g., a total specular reflection less than about 10%, about 5%, or less for a silicon substrate). Since the substrates have such a low total spectral reflection, devices including the substrates do not need sun-tracking mechanisms, which reduces the overall cost.

In an embodiment, the method of making the antireflective layer is easier, faster, and/or less expensive than other techniques for making similar structures. In an exemplary embodiment, the method of forming an antireflective layer on a base substrate includes disposing a polyimide substrate over a first area of the base substrate, where a second area of the base substrate does not include the polyimide substrate. Subsequently, the base substrate is etched to form the broadband antireflective layer in the second area of the base substrate, while the first area is not etched.

In an exemplary embodiment, the etching can include a reactive ion etching process (e.g., chlorine reactive ion etching process). The etching process forms the antireflective layer. The conditions (e.g., temperature, chemical reactants, chamber pressure, gas flow rate, etching power and duration, etc.) of the etching process can be adjusted to modify the physical characteristics (e.g., thickness of the antireflective layer, one or more dimensions of the pillars that form the antireflective layer, and the like) of the antireflective layer. Additional details regarding the etching process are described in the Examples.

In an aspect, the polyimide substrate can be placed in any area on the base substrate such as the middle area so that the second area can be on either side of the polyimide substrate. In an aspect, multiple polyimide substrates can be placed on the base substrate. In an embodiment, the polyimide substrate can have a width of about 0.5 inch to 1.5 inch, a length of about 1 inch to 5 inch, and a thickness of about 100 μm to 500 μm. In an aspect, the polyimide substrate can be a polyimide tape including all aromatic heterocyclic polyimides and linear polyimides (e.g., poly(4,4′-oxydiphenylene-pyromellitimide).

Although not intending to be bound by theory, the etching process can include the formation of a plurality of polyimide particles (e.g., nanoparticles (e.g., about 1 nm to 100 nm)) that form a polyimide mask (e.g., randomly formed) in the second area of the substrate (e.g., crystalline silicon substrate). The polyimide particles “mask” portions of the substrate and pillars are randomly formed to create the antireflective layer.

In an exemplary embodiment, the base substrate can include a silicon substrate, a gallium arsenide (GaAs) substrate, a gallium antimonide (GaSb) substrate, indium phosphide (InP), gallium nitride (GaN), and the like. In an embodiment, the silicon substrate can include a single crystalline silicon substrate, a multi-crystalline substrate, or an amorphous silicon substrate. In an embodiment, the substrate can have a thickness of about 2 μm to 1000 μm and the length and width can vary depending upon the desired use or application (e.g., 4 inches or more).

In an exemplary embodiment, the base substrate can be processed to form the antireflective layer. In an embodiment, the antireflective layer can be referred to as a moth-eye grating. In an embodiment, the antireflective layer has a total specular reflection of about 10% or less, about 8%, or less, about 5% or less, about 3% or less, or about 1% or less, for the entire visible wavelength at an incident angle of about 0° to 180°. The phrase “total specular reflection” means the overall specular reflection obtained from a substrate surface with reflection angle between 0 and 180 degrees. An integration sphere can be used in measuring total specular reflection.

In an aspect, the broadband antireflective layer can have a total specular reflection of less than 10% at wavelength of about 400 to 800 nm, of less than 5% at wavelength of about 450 to 800 nm, or of less than 3% at wavelength of about 500 to 750 nm, for a substrate such as silicon dioxide.

In an aspect, the dimensions (e.g., height, diameter, length) are not uniform and are random. In an exemplary embodiment, the antireflective layer has a height (or depth of the etched structure) of about 500 nm to 2000 nm or about 500 nm to 1000 nm. In an aspect, the pillar are not uniformly space apart (e.g., randomly spaced apart). In an embodiment, the pillars (some or all of the pillars) can have a spacing of about 10 nm to 300 nm between a pair of pillars as measured from the pillar base to pillar base, where the spacing can vary between multiple pairs of pillars.

In an embodiment, one or more of the pillars can have a diameter at the base of about 50 to 300 nm or about 50 to 150 nm. The pillar may have the same or different diameter along the length of the pillar. In an embodiment, the pillar tapers from the base to the top of the pillar, where the diameter of the pillar at the midpoint of the length of the pillar can be about 50 nm to 300 nm or about 50 to 150 nm.

In an embodiment, one or more of the pillars can have a length or height of about 100 to 2000 nm or about 100 nm to 1000 nm. In an embodiment, the length of the pillars can vary depending on the surface morphology of the substrate so that some pillars are much longer than others.

In an aspect, the base substrate can include an area that has the antireflective layer. In an aspect, the reflective layer has a total specular reflection of less than 10% at wavelength of about 400 to 800 nm, of less than 5% at wavelength of about 450 to 800 nm, or of less than 3% at wavelength of about 500 to 750 nm. In an aspect, the antireflective layer has a plurality of pillars that are not uniformly spaced apart from one another. In an aspect, the antireflective layer can have a height of about 500 nm to 1000 nm. In an aspect, the plurality of pillars that can have a spacing of about 10 nm to 300 nm between a pair of pillars as measured from pillar base to pillar base, and the pillar has a diameter at the base of about 50 to 300 nm. In an embodiment, the base substrate can be: a silicon substrate, a gallium arsenide (GaAs) substrate, a gallium antimonide (GaSb) substrate, indium phosphide (InP), and gallium nitride (GaN), and in particular can be a silicon substrate.

While embodiments of the present disclosure are described in connection with the Example and the corresponding text and figures, there is no intent to limit the disclosure to the embodiments in these descriptions. On the contrary, the intent is to cover all alternatives, modifications, and equivalents included within the spirit and scope of embodiments of the present disclosure.

### Example 1

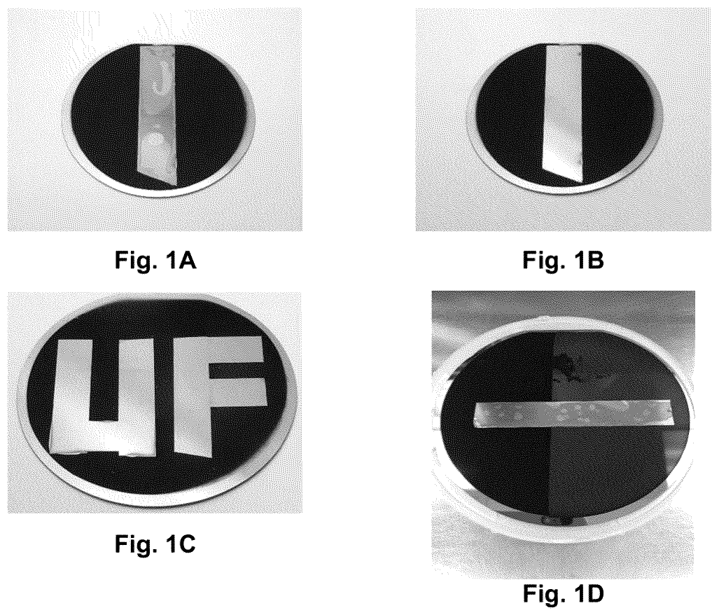

Unlike most of the existing surface texturing approaches, the methodology disclosed herein for making the black silicon (BSi) is more straightforward. Described is a self-masking etching process that does not involve any lithographic technique and is using an intact “Kapton®” polyimide tape (poly (4,4′-oxydiphenylene-pyromellitimide)). By using a chlorine reactive ion etching (RIE) recipe for a moth-eye anti-reflection coating (see Wei-Lun Min, Bin Jiang, Peng Jiang, Bioinspired Self-Cleaning Antireflection Coatings. Advanced Materials, 20, 3914-3918, 2008, herein incorporated by reference), the sample can be made with the tape simply applied on the surface of the silicon wafer prior to RIE processing. FIGS. 1A-1D show photographs of the as-prepared BSi wafers. It can be clearly seen from FIGS. 1B and 1C that the tape-covered regions are unchanged while the uncovered bare silicon (100) surface turned quite dark. As a comparison, as shown in FIG. 1D, the previously reported “moth-eye” anti-reflection coating (right half of the wafer) appears a bit grey and reflective. Notice that the defective region (uncovered wafer) on the moth-eye region also turned as dark as the BSi area.

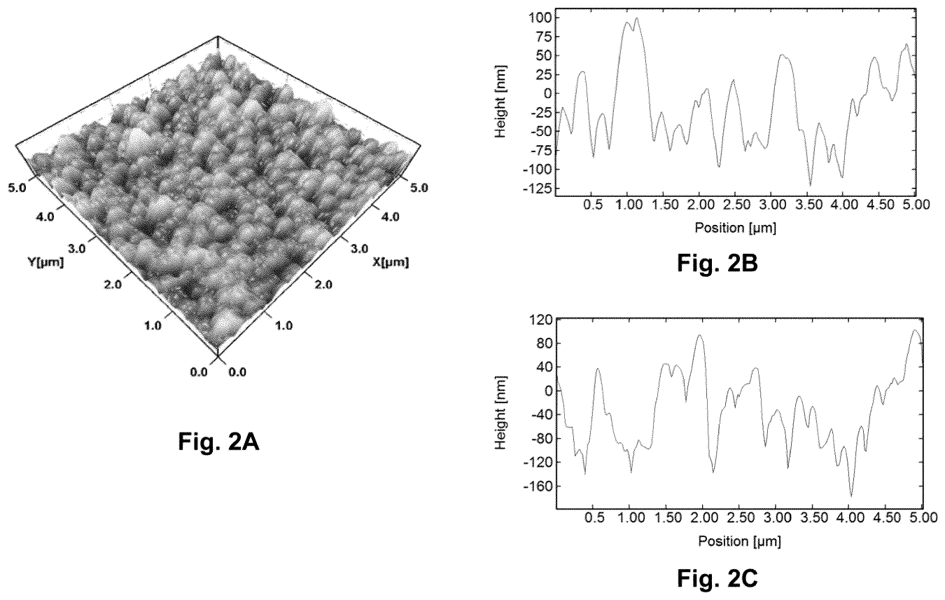

Atomic force microscopy (AFM) is a powerful tool for analysing the surface morphology. As shown is FIG. 2A, the 3-D reconstruction confirmed the presence of random, nanoscopic surface textures. The height profiles along the X and Y axis are shown in FIGS. 2B and 2C, respectively. The irregular nanopillar height and inter-pillar distances are evident, indicating there are micro-masks formed during RIE that randomly distributed on the whole wafer.

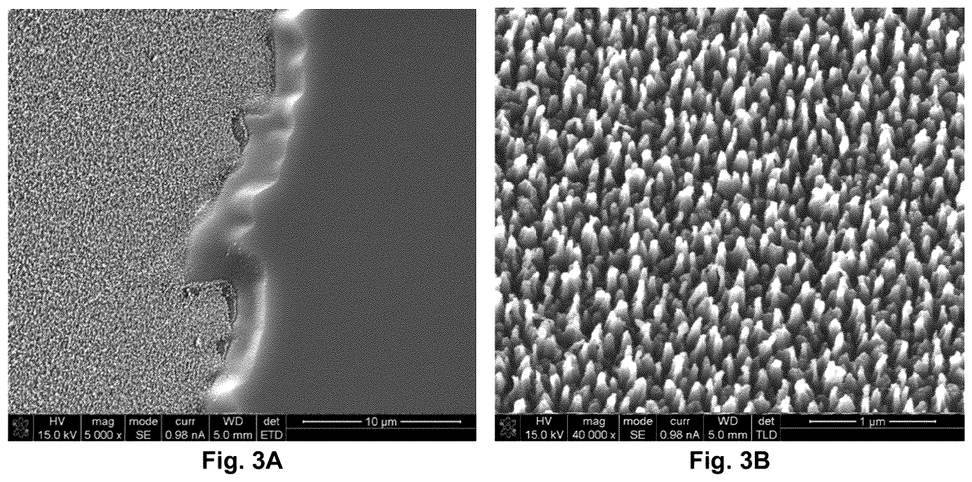

FIGS. 3A-3B show the scanning electron microscope images of the same sample. FIG. 3A shows the top view of the sample with a tilt angle of 10 degrees with an apparent boundary between the etched (left) and polyimide tape-covered (right) surfaces. It is apparent that the tape-covered surface is much smoother than the etched one. FIG. 3B shows the magnified top view of the etched surface with the same tilt angle.

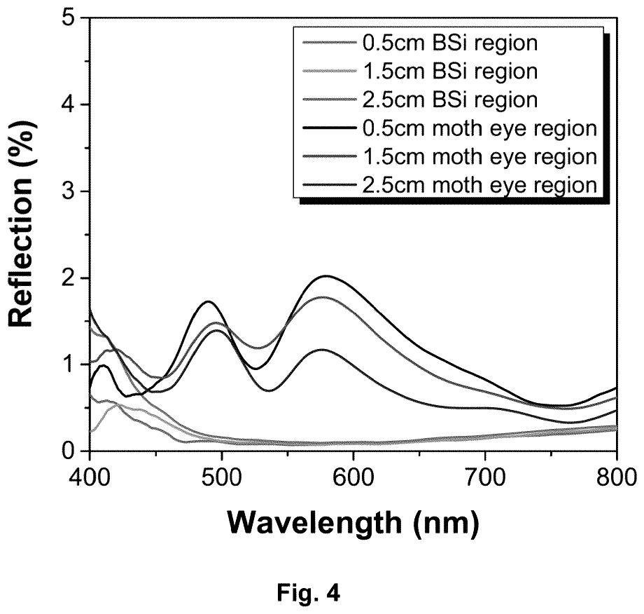

FIG. 4 compares the normal-incidence optical reflectance spectra obtained from the BSi region (left) and the templated moth-eye region (right) of the wafer shown in FIG. 1D. The different BSi regions (indicated by the distances from the central polyimide tape) consistently show lower reflection (three lowest lines) than those of the moth-eye regions. In addition, the BSi antireflection coatings are broadband as indicated by the low reflection over a broad range of wavelengths (from 400 to 800 nm).

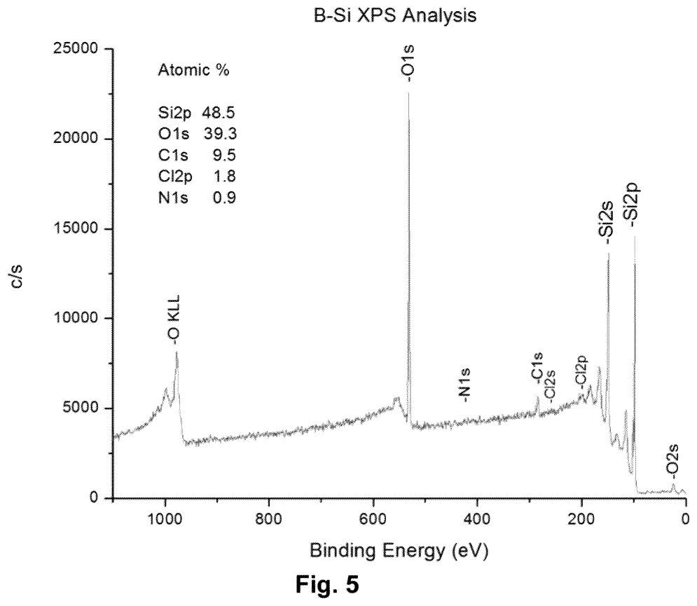

FIG. 5 shows the X-ray photoelectron spectroscopy (XPS) spectrum of the BSi surface. XPS is a great tool for analysing surface elemental composition. The atomic composition, along with the AFM and SEM images, indicate that the low reflectance is due to surface texture rather than any compound being made during the fabrication process that absorbs light. One possible explanation for the dark appearance of the processed silicon wafers is the deposition of black carbon on the wafer surfaces, possibly caused by plasma-enhanced carbonization of polyimide tapes. However, this hypothesis can be excluded by the XPS analysis as only small amount of carbon (˜9.5 atom %) is present on the wafer surface. The sample surface is composed of mainly silicon and oxygen. The autonomous and inevitable oxidation of silicon by oxygen in air can explain the high surface concentration of oxygen atoms.

It should be noted that ratios, concentrations, amounts, and other numerical data may be expressed herein in a range format. It is to be understood that such a range format is used for convenience and brevity, and thus, should be interpreted in a flexible manner to include not only the numerical values explicitly recited as the limits of the range, but also to include all the individual numerical values or sub-ranges encompassed within that range as if each numerical value and sub-range is explicitly recited. To illustrate, a concentration range of “about 0.1% to about 5%” should be interpreted to include not only the explicitly recited concentration of about 0.1 wt % to about 5 wt %, but also include individual concentrations (e.g., 1%, 2%, 3%, and 4%) and the sub-ranges (e.g., 0.5%, 1.1%, 2.2%, 3.3%, and 4.4%) within the indicated range. In an embodiment, the term “about” can include traditional rounding according to significant figures of the numerical value. In addition, the phrase “about ‘x’ to ‘y’” includes “about ‘x’ to about ‘y’”.

While only a few embodiments of the present disclosure have been shown and described herein, it will become apparent to those skilled in the art that various modifications and changes can be made in the present disclosure without departing from the spirit and scope of the present disclosure. All such modification and changes coming within the scope of the appended claims are intended to be carried out thereby.

1. A structure comprising:
a base substrate having a polyimide substrate disposed over a first area of the base substrate and second area having a broadband antireflective layer that has a total specular reflection of less than 10% at a wavelength of about 400 to about 800 nm.

2. The structure of claim 1, wherein the broadband antireflective layer has a plurality of pillars that are not uniformly and are randomly spaced apart from one another.

3. The structure of claim 1, wherein the plurality of pillars are non-uniformly sized, wherein the broadband antireflective layer has a height of about 500 nm to about 1000 nm, and at least one pillar has a diameter at the base of about 50 to 300 nm.

4. The structure of claim 1, wherein the plurality of pillars that have a spacing of about 10 nm to 300 nm between a pair of pillars as measured from pillar base to pillar base, and at least one pillar has a diameter at the base of about 50 to 300 nm.

5. The structure of claim 1, wherein the broadband antireflective layer has a plurality of pillars that are not uniformly and are randomly spaced apart from one another, wherein the plurality of pillars are non-uniformly sized, wherein the broadband antireflective layer has a height of about 500 nm to about 1000 nm, and at least one pillar has a diameter at the base of about 50 to 300 nm.

6. The structure of claim 1, wherein the broadband antireflective layer has a plurality of pillars that are not uniformly and are randomly spaced apart from one another, wherein the plurality of pillars that have a spacing of about 10 nm to 300 nm between a pair of pillars as measured from pillar base to pillar base, and at least one pillar has a diameter at the base of about 50 to 300 nm.

7. The structure of claim 1, wherein the base substrate is selected from the group consisting of: a silicon substrate, a gallium arsenide (GaAs) substrate, a gallium antimonide (GaSb) substrate, indium phosphide (InP), and gallium nitride (GaN).

8. The structure of claim 1, wherein the broadband antireflective layer has a plurality of pillars that are not uniformly and are randomly spaced apart from one another, wherein the broadband antireflective layer has a total specular reflection of less than 5% at wavelength of about 450 to about 800 nm.

9. The structure of claim 1, wherein the broadband antireflective layer has a plurality of pillars that are not uniformly and are randomly spaced apart from one another, wherein the broadband antireflective layer has a total specular reflection of less than 3% at wavelength of about 500 to about 750 nm.

10. The structure of claim 1, wherein the broadband antireflective layer has a plurality of pillars that are not uniformly and are randomly spaced apart from one another, wherein the base substrate is a crystalline silicon.

11. The structure of claim 1, wherein the broadband antireflective layer has a plurality of pillars that are not uniformly and are randomly spaced apart from one another, wherein the base substrate is selected from the group consisting of: a silicon substrate, a gallium arsenide (GaAs) substrate, a gallium antimonide (GaSb) substrate, indium phosphide (InP), and gallium nitride (GaN).

13. The structure of claim 1, wherein the broadband antireflective layer has a plurality of pillars that are randomly spaced apart from one another.

14. The structure of claim 13, wherein the plurality of pillars are non-uniformly sized, wherein the broadband antireflective layer has a height of about 500 nm to about 1000 nm, and at least one pillar has a diameter at the base of about 50 to 300 nm.

15. The structure of claim 13, wherein the plurality of pillars that have a spacing of about 10 nm to 300 nm between a pair of pillars as measured from pillar base to pillar base, and at least one pillar has a diameter at the base of about 50 to 300 nm.

16. The structure of claim 1, wherein the broadband antireflective layer has a plurality of pillars that are randomly spaced apart from one another, wherein the plurality of pillars are non-uniformly sized.

17. A structure comprising:
a base substrate having a polyimide substrate disposed over a first area of the base substrate and second area having a broadband antireflective layer, wherein the broadband antireflective layer has a plurality of pillars that are not uniformly and are randomly spaced apart from one another, wherein the plurality of pillars are non-uniformly sized.
